(19) United States
(12) Patent Application Publication
(10) Pub. No.: US 2008/0302507 A1
(43) Pub. Date: Dec. 11, 2008

(54) Adjustable cooling apparatus

(75) Inventor: Michael Chen, Taipei Hsien (TW)

Correspondence Address: Joe McKinney Muncy, PO Box 1364, Fairfax, VA, 22038-1364, US

(73) Assignee: TOPOWER COMPUTER INDUSTRIAL CO., LTD.

(21) Appl. No.: 11/806,938

(22) Filed: Jun. 5, 2007

(51) Int. Cl. H05K 7/20

(52) U.S. Cl. 165/80.3; 165/104.33; 361/697

(57) ABSTRACT

An adjustable cooling apparatus to disperse heat generated by an electronic device mainly includes a heat transfer portion attached to the electronic device to transfer heat generated by the electronic device and a heat dispersing portion to receive the heat from the heat transfer portion and disperse the heat. The heat transfer portion and the heat dispersing portion are coupled through a toggle mechanism such that the heat dispersing portion can be tilted relative to the heat transfer portion at an angle which is adjustable. The cooling apparatus is mounted onto the electronic device through a base. The base has a turning mechanism coupling with the heat transfer portion so that the cooling apparatus is swivelable in a desired direction relative to the electronic device. An air fan is fastened to the heat dispersing portion to drive airflow to pass through the heat dispersing portion to improve cooling efficiency.

### FIELD OF THE INVENTION

The present invention relates to a cooling apparatus and particularly to a cooling apparatus with an adjustable heat dispersing direction to be used on electronic devices.

### BACKGROUND OF THE INVENTION

These days the performance and speed of electronic products improve very rapidly. With advance of material technology the electronic products have been made smaller and lighter. To build high performance in a smaller size, reliability becomes an important issue. An electronic device generates heat during high speed process that affects product reliability. As the size of the electronic device becomes smaller, heat accumulation in the interior of the device is a big problem which the industry constantly tries to figure out a better solution.

The commonly adopted cooling techniques for electronic devices at present can be divided into active cooling and passive cooling. Active cooling, such as cooling fans and water circulation, uses an extra driving source to accelerate cooling effect. Passive cooling includes heat transfer ducts and radiation fins, and does not need an external driving source. It is in contact with the electronic device to transfer heat. Through phase change of a cooling liquid contained inside and a large area of radiation surface heat can be dispersed into the atmosphere. In the present techniques the active cooling and passive cooling often are being used independently or jointly.

R.O.C. patent publication Nos. 231102,299851, 200636435, and patent Nos. M307287 and M302867 disclose techniques that couple active cooling and passive cooling. Heat generated by electronic devices is transferred by passive cooling elements, then is carried away by airflow driven by an active cooling element (cooling fan) to speed up cooling effect. On active cooling elements and passive cooling elements, cooling efficiency can be improved by mounting them on desired locations or forming them with desired shapes. However, the conventional active and passive cooling elements mostly are installed in a fixed manner, and disperse heat only in a single direction. As the internal elements of electronic products often are arranged in a complex manner and form obstacles in an irregular space, cooling airflow in one direction cannot be smoothly discharged, and turbulence often happens. As the prevailing trend demands thin and light, the internal space of electronic products has to be fully utilized. Hence heat trapping and accumulation in the small internal space becomes a serious problem.

### SUMMARY OF THE INVENTION

The primary object of the present invention is to provide a cooling apparatus with an adjustable heat dispersing direction to resolve the problems of airflow turbulence and heat accumulation in electronic products that occur to the conventional techniques by dispersing heat in only one direction. To achieve the foregoing object the present invention provides an adjustable cooling apparatus to be used on electronic devices to disperse heat. It mainly includes a heat transfer portion to transfer heat of an electronic device and a heat dispersing portion to receive and disperse the heat from the heat transfer portion. The heat transfer portion and the heat dispersing portion are coupled through a toggle mechanism. The toggle mechanism includes a first coupling unit connecting to the heat transfer portion and a second coupling unit connecting to the heat dispersing portion. The first and second coupling units are pivotally coupled through a shaft so that they can be swiveled relative to each other. The heat dispersing portion and the heat transfer portion may form an angle relative to each other that is adjustable through the toggle mechanism which serves as an axis. Moreover, the heat transfer portion has a base mounted onto the electronic device. The base has a turning mechanism fastened to the heat transfer portion. The turning mechanism includes a first turning unit fastened to the base and a second turning unit fastened to the heat transfer portion. Thus the swivel direction of the cooling apparatus relative to the electronic device can be adjusted. To improve cooling efficiency an air fan is installed on the heat dispersing portion to drive airflow to pass through the heat dispersing portion to speed up heat dispersion.

The adjustable cooling apparatus of the invention has the toggle mechanism and turning mechanism to adjust the heat dispersing direction. Besides adjusting the heat dispersing direction in response to the internal space of the electronic device to achieve faster cooling effect for the electronic device, the heat dispersing direction may also be adjusted and directed towards the interior or electronic elements of other electronic products to drive airflow to pass through to aid cooling effect. Hence an optimal cooling efficiency can be achieved for the entire set of electronic product.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of an embodiment of the invention.

FIG. 2 is an exploded view of an embodiment of the invention.

FIG. 3 is a sectional view of an embodiment of the invention.

FIG. 4A is a side view of an embodiment of the invention showing a start position for vertical swiveling.

FIGS. 4B and 4C are side views of an embodiment of the invention showing moving positions in vertical swiveling.

FIG. 5 is a side view of an embodiment of the invention showing a moving position in horizontal swiveling.

### DETAILED DESCRIPTION OF THE PREFERRED EMBODIMENT

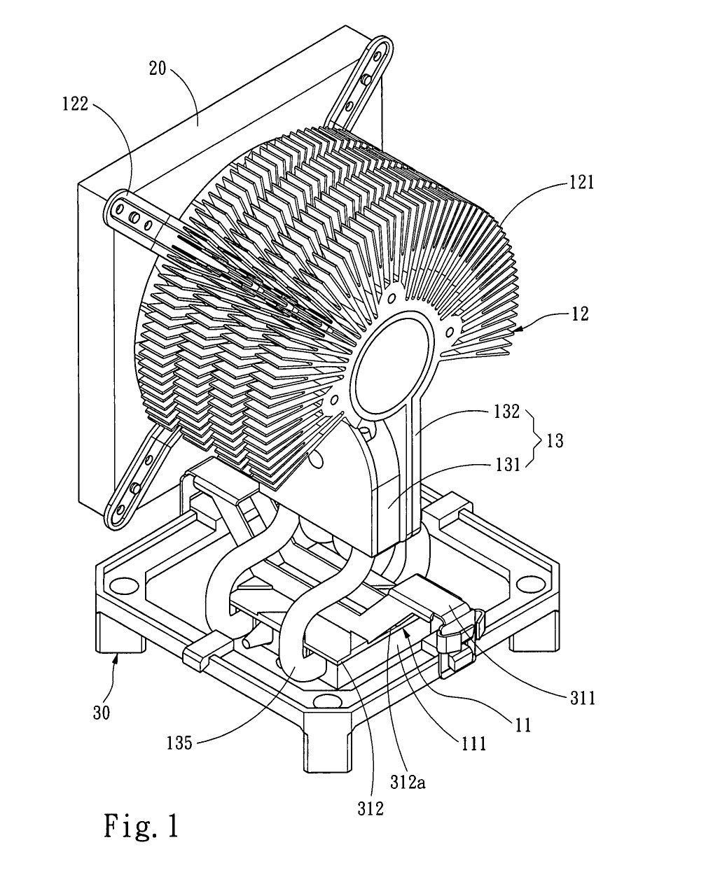

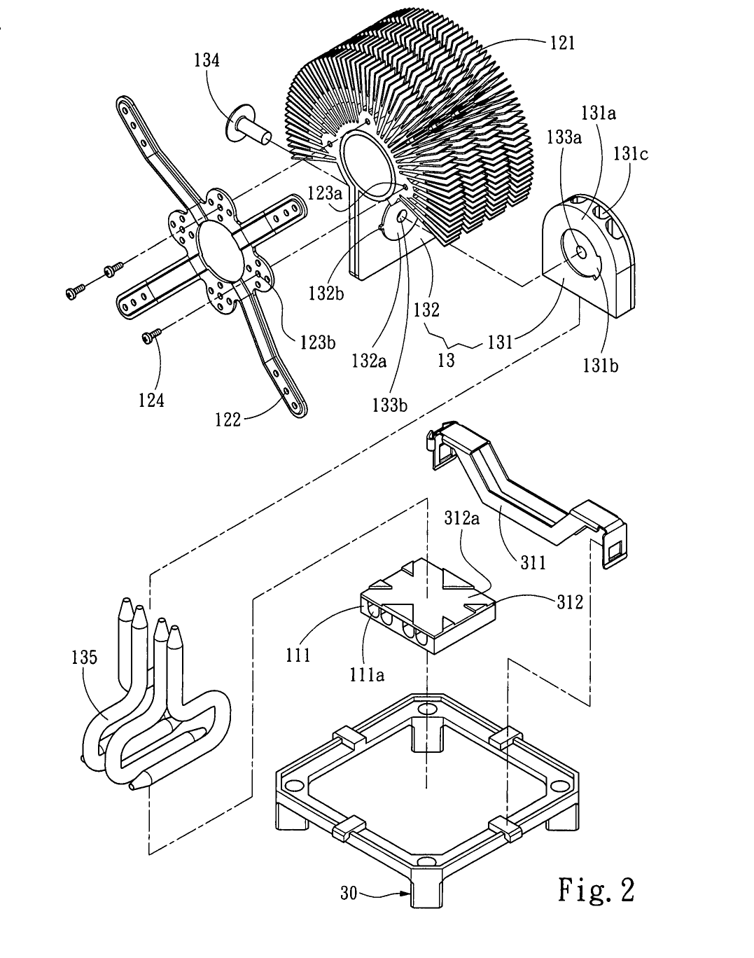

Please refer to FIGS. 1 and 2 for an embodiment of the invention. The adjustable cooling apparatus of the invention is aims to disperse heat generated by an electronic device (not shown in the drawings). It mainly includes a heat transfer portion 11 to transfer heat of the electronic device and a heat dispersing portion 12 to receive the heat from the heat transfer portion 11 and disperse the heat. The heat transfer portion 11 has a heat transfer member 111 attached to a heat source of the electronic device. The heat dispersing portion 12 has a radiation fin assembly 121. The cooling apparatus further has a toggle mechanism 13 to couple the heat transfer portion 11 and the heat dispersing portion 12. The heat dispersing portion 12 and the heat transfer portion 11 form an angle between them that can be adjusted about an axis served by the toggle mechanism 13. The toggle mechanism 13 includes a heat transfer duct 135 coupled with the heat transfer portion 11. The heat dispersing portion 12 has a fan bracket 122 to hold an air fan 20 of a varying size. The heat dispersing portion 12 and the fan bracket 122 have corresponding screw holes 123a and 123b that are fastened through bolts 124 so that the fan bracket 122 can be fastened to the heat dispersing portion 12. The air fan 20 is driven by an external power to generate forced airflow to pass through the heat dispersing portion 12 to accelerate dispersion of the heat transferred to the heat dispersing portion 12.

The cooling apparatus of the invention further has a base 30 mounted onto the electronic device. The base 30 has a turning mechanism fastened to the heat transfer portion 11. The turning mechanism includes a first turning unit 311 coupled with the base 30 and a second turning unit 312 coupled with the heat transfer member 111 of the heat transfer portion 11. The first turning unit 311 and the second turning unit 312 are swivelable relative to each other such that the heat transfer portion 11 and the heat dispersing portion 12 can be swiveled to a direction desired relative to the base 30. Moreover, the second turning unit 312 has at least one retaining means 312a connecting to the first turning unit 311 to anchor the heat transfer portion 11 in a swivel direction. The retaining means 312a has a groove to tightly hold the first turning unit 311 so that after the swivel direction of the first turning unit 311 has been adjusted it can be anchored temporarily.

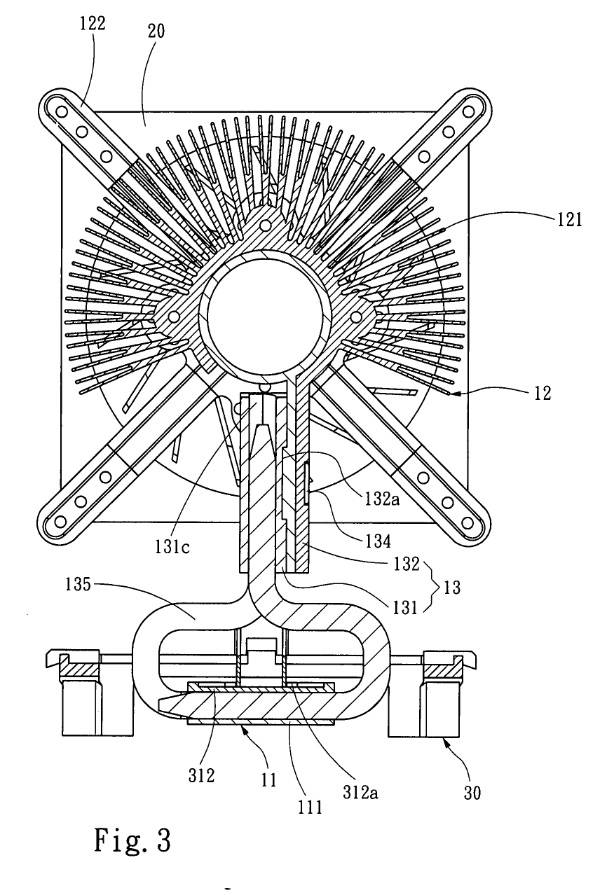

Referring to FIGS. 2 and 3, the toggle mechanism 13 includes a first coupling unit 131 coupled with the heat transfer portion 11 and a second coupling unit 132 coupled with the heat dispersing portion 12. The first and second coupling units 131 and 132 have respectively corresponding apertures 133a and 133b to be run through by an anchor shaft 134 to fasten the first and second coupling units 131 and 132. The second coupling unit 132 has a boss 132a to wedge in a recess 131a formed on the first coupling unit 131. The recess 131a has a retaining notch 131b. The boss 132a has a retaining flange 132b corresponding to the retaining notch 131b. When the boss 132a is held in the recess 131a the retaining flange 132b can be moved in the retaining notch 131b to define a retaining range to confine the swiveling range of the heat transfer portion 11 and the heat dispersing portion 12. To facilitate heat dispersion into the atmosphere from the heat source in the electronic device through the heat transfer portion 11, toggle mechanism 13 and heat dispersing portion 12, the first coupling unit 131 and the second coupling unit 132 must be in contact tightly to prevent forming an air insulation layer to hinder heat transfer. In addition, the heat transfer member 111 and the first coupling unit 131 have respectively a passage 111a and 131c to hold the heat transfer duct 135 tightly. Thereby contact area can be increased to transfer the heat from the heat transfer member 111 to the first coupling unit 131.

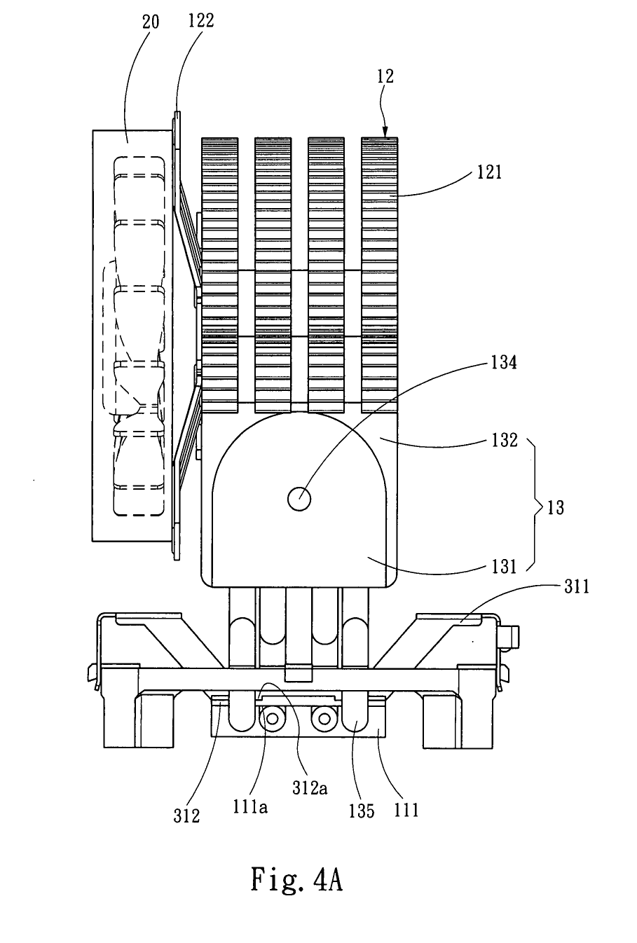

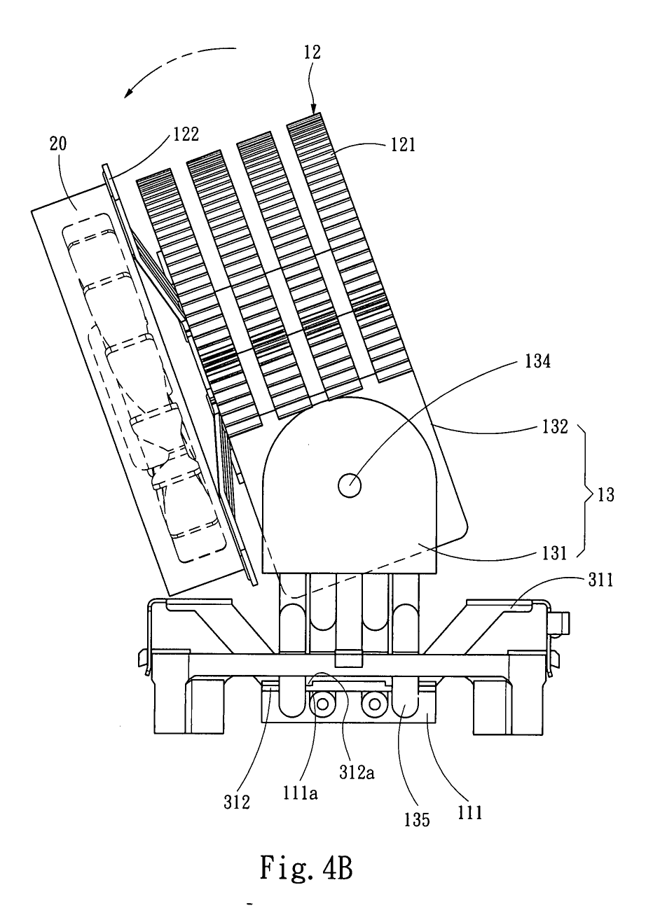

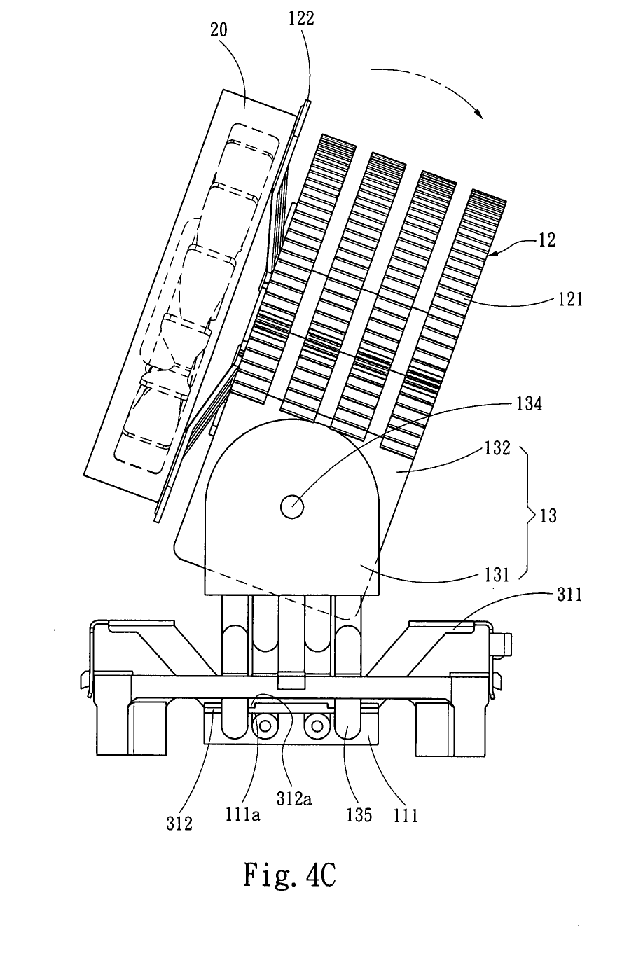

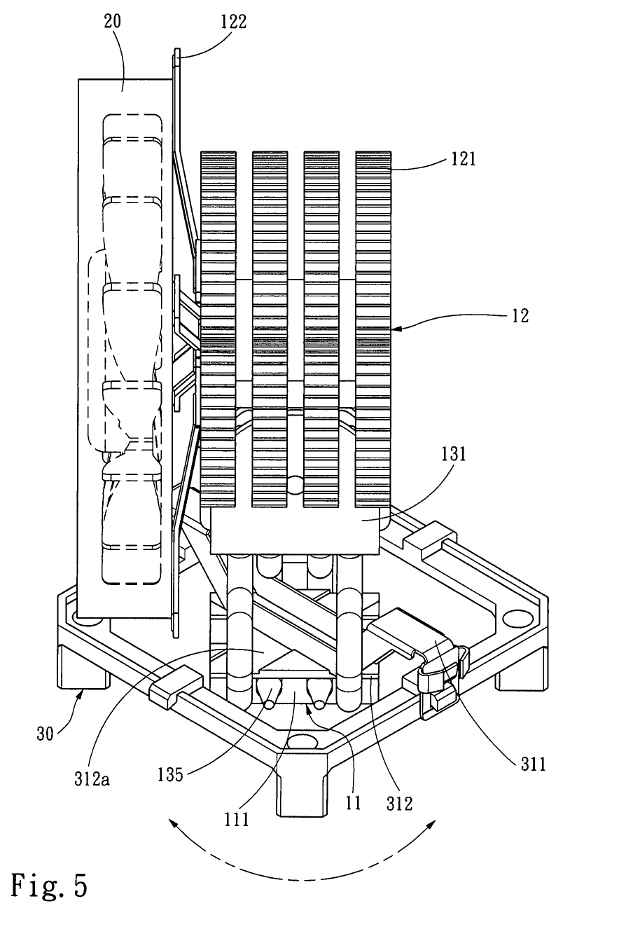

In the embodiment set forth above the heat dispersing portion 12 and the heat transfer portion 11 can be swiveled relative to each other through the toggle mechanism 13. Based on the position of the heat dispersing portion 12 a vertical swivel start position (referring to FIG. 4A) and a vertical swivel moving position (referring to FIGS. 4B and 4C) can be defined. The moving position of the heat dispersing portion 12 is limited by the retaining range. When swiveling vertically to adjust the angle of heat dispersion, the heat dispersing portion 12 is swiveled from the vertical swivel start position to the moving position, meanwhile the retaining flange 132b of the second coupling unit 132 is moved in the space of the retaining notch 131b, and the second coupling member 132 also drives the heat dispersing portion 12 to tilt at a desired adjusting angle. Hence when the air fan 20 drives airflow to pass through the heat dispersing portion 12 a desired heat dispersing direction can be achieved through the tilted angle. On the other hand the cooling apparatus of the invention can also be swiveled horizontally through the turning mechanism. Based on the position of the heat transfer portion 11 a horizontal swivel start position (referring to FIG. 1) and a horizontal swivel moving position (referring to FIG. 5) can be defined. The heat transfer portion 11 is located on the second turning unit 312. Hence the heat transfer portion 11 at the horizontal swivel start position can be in contact with the first turning unit 311 according to different directions of the retaining means 312a on the second turning unit 312, and be moved to different positions. Thereby heat dispersion can be adjusted in a desired horizontal direction.

The cooling structure of the invention, aside from dispersing heat for the mounting electronic device, because of the air fan 20 to provide driving airflow to improve cooling effect and the special design of the toggle mechanism 13 and turning mechanism to adjust direction, the heat dispersing portion 12 can be adjusted in multiple directions. Thus the airflow can be channeled to the internal space of the electronic product and other electronic devices in the surrounding. Therefore a cooperative cooling effect can be achieved. As the electronic products are increasingly made at a smaller size, the internal space is shrunk. The cooperative cooling effect provided by the invention can reduce the number of cooling apparatus to be installed, and can improve utilization of the internal space. It also can reduce electric power consumption. In short, the adjustable cooling apparatus of the invention can be adjusted in multiple directions to provide cooling effect. It offers a significant improvement over the conventional cooling apparatus (especially those adopt the active cooling technique) which provide cooling in only one direction that could result in air turbulence and trapping and accumulation of heat due to space obstacles inside the electronic device. Moreover, the adjustable cooling apparatus of the invention, aside from being used independently, also can adjust heat dispersing direction to allow the airflow to be directed to other electronic devices to aid cooling of other electronic devices nearby. As a result, the cooling efficiency of the entire electronic product set is enhanced. The internal space and power consumption of the electronic product can be reduced. It is a more practical and economic effective design.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. An adjustable cooling apparatus attached to an electronic device to transfer heat generated by the electronic device, comprising:
a heat transfer portion to transfer the heat from the electronic device;
a heat dispersing portion to receive the heat from the heat transfer potion and disperse the heat; and
a toggle mechanism coupling the heat transfer portion and the heat dispersing portion such that an angle is formed between the heat transfer portion and the heat dispersing portion that is adjustable about an axis served by the toggle mechanism.

2. The adjustable cooling apparatus of claim 1, wherein the toggle mechanism includes a first coupling unit connecting to the heat transfer portion and a second coupling unit connecting to the heat dispersing portion, the first and the second coupling units have respectively a corresponding aperture to be run through by a shaft to fasten the first and the second coupling units.

3. The adjustable cooling apparatus of claim 2, wherein the second coupling unit has a retaining flange and the first coupling unit has a retaining notch which holds the retaining flange and forms a moving range of the retaining flange.

4. The adjustable cooling apparatus of claim 1, wherein the toggle mechanism includes a plurality of heat transfer ducts connecting to the heat transfer portion.

5. The adjustable cooling apparatus of claim 1 further having a based which is mounted onto the electronic device and has a turning mechanism coupling with the heat transfer portion.

6. The adjustable cooling apparatus of claim 5, wherein the turning mechanism includes a first turning unit coupling with the base and a second turning unit coupling with the heat transfer portion.

7. The adjustable cooling apparatus of claim 6, wherein the second turning unit has at least one retaining means in contact with the first turning unit.

8. The adjustable cooling apparatus of claim 7, wherein the retaining means is a groove to form a tight coupling with the first turning unit.

9. The adjustable cooling apparatus of claim 1, wherein the heat transfer portion has a heat transfer member to transfer the heat of the electronic device.

10. The adjustable cooling apparatus of claim 1, wherein the heat dispersing portion has a radiation fin assembly.

11. The adjustable cooling apparatus of claim 1, wherein the heat dispersing portion has an air fan.

12. The adjustable cooling apparatus of claim 11, wherein the air fan is fastened to the heat dispersing portion through a fan bracket.
